(19) United States
(12) Patent Application Publication
(10) Pub. No.: US 2013/0059403 A1
(43) Pub. Date: Mar. 7, 2013

(54) METHOD AND APPARATUS FOR WAFER TEMPERATURE MEASUREMENT USING AN INDEPENDENT LIGHT SOURCE

(71) Applicants: Jared Ahmad Lee, Santa Clara, CA (US); Jiping Li, Palo Alto, CA (US)

(72) Inventors: Jared Ahmad Lee, Santa Clara, CA (US); Jiping Li, Palo Alto, CA (US)

(73) Assignee: Applied Materials, Inc., Santa Clara, CA (US)

(21) Appl. No.: 13/539,340

(22) Filed: Jun. 30, 2012

Related U.S. Application Data
(60) Provisional application No. 61/531,327, filed on Sep. 6, 2011.

(51) Int. Cl. H01L 21/66; H01L 21/306

(52) U.S. Cl. 438/17; 156/345.27; 257/E21.521

(57) ABSTRACT

An apparatus is provided for measuring a substrate temperature during an etching process, comprising: one or more windows formed in a substrate supporting surface; a first signal generator configured to pulse a first signal; and a first sensor positioned to receive energy transmitted from the first signal generator through the one or more windows. A method is provided for measuring a substrate temperature during an etching process comprising: heating a substrate using radiant energy; pulsing a first light; determining a metric indicative of total transmittance through the substrate when the first light is pulsed on; determining a metric indicative of background transmittance through the substrate when the first light is pulsed off; and determining a process temperature.

### CROSS-REFERENCE TO RELATED APPLICATION/PRIORITY CLAIM

This application claims the benefit of U.S. Provisional Application No. 61/531,327, filed on Sep. 6, 2011, which is herein incorporated by reference in its entirety.

### BACKGROUND OF THE INVENTION

1. Field of the Invention

Aspects of the present invention generally relate to a method and apparatus for measuring a semiconductor substrate temperature. Further, aspects of the present invention relate to non-contact wafer temperature measurement in an infrared heating environment. More specifically, a method and apparatus for measuring a semiconductor substrate temperature in an etch process by substrate infrared transmission.

2. Description of the Related Art

Ultra-large-scale integrated (ULSI) circuits may include more than one billion electronic devices (e.g., transistors) that are formed on a semiconductor substrate, such as a silicon (Si) substrate, and cooperate to perform various functions within the device. During processing, a number of thermal processing steps are occasionally performed on the substrate surface. Thermal processing typically requires precise substrate temperature measurement for process control. Inaccurate substrate temperature control may result in poor process results that may adversely influence device performance and/or result in substrate film material damage.

Different types of temperature measurement tools may be used to measure substrate temperature during processing. For example, thermocouples are often used to measure a substrate temperature by physically contacting the substrate at predetermined locations on the substrate surface. However, with larger diameter substrates, the overall temperature variation across substrate surface is difficult to determine due to the large distances between measurement locations. Furthermore, the reliability of the thermal physical contact of the thermocouples to the substrate surface is hard to control and has contamination concerns.

Alternatively, optical pyrometry is sometimes used to measure substrate temperature. Radiation emitted from the substrate surface during processing is measured by an optical pyrometry sensor to determine the substrate temperature. However, the measurement of optical emissions from substrate surface is difficult to separate from background noise, such as intense lighting from heating elements or heat from a plasma source, optical emissions from chamber wall and/or stray light from windows. As the optical emissions from the substrate surface may not be accurately measured and the background noise may further introduce error to temperature measurement, the actual substrate surface temperature is difficult to precisely measure, which may result in erroneous substrate temperature determination and consequently poor processing results.

Therefore, there is a need for improved apparatuses and methods for substrate temperature measurement.

### SUMMARY OF THE INVENTION

Apparatuses and methods for measuring temperature during a process are provided. In one embodiment, an apparatus is provided for measuring a substrate temperature during an etching process, comprising: a chamber body having a chamber lid enclosing the chamber body; a substrate support assembly disposed in the chamber body and having a substrate supporting surface; one or more windows formed in the substrate supporting surface; a first signal generator configured to pulse a first signal, wherein the first signal generator is optically coupled through the substrate support assembly to the one or more windows such that the pulsed signal may be transmitted through the one or more windows; and a first sensor positioned to receive energy transmitted from the first signal generator through the one or more windows, wherein the first sensor is configured to detect a metric indicative of transmittance.

In another embodiment, the first signal generator is a laser configured to pulse a wavelength of light, and wherein the first sensor is configured to detect that wavelength of light. In a further embodiment, one or more heating lamps are provided, which when powered on can emit light of at least the same wavelength as the first signal generator, wherein the light is infrared light of a wavelength between about 1000 nm and 1500 nm, and wherein the first sensor is positioned to detect the wavelength of infrared light from (a) the first signal generator and the one or more heating lamps when the first signal generator is pulsed on, and (b) the one or more heating lamps when the first signal generator is pulsed off.

Another embodiment further comprises a computing device programmed, wired or otherwise configured to determine a change in transmission from the first signal passing through a substrate positioned on the substrate supporting surface, wherein the computing device subtracts (a) values representing transmittance of infrared light through the substrate from the one or more heating lamps when the first signal is pulsed off, from (b) values representing transmittance of infrared light through the substrate from the one or more heating lamps and the first signal when the first signal is pulsed on, and wherein the computing device determines a temperature of the substrate. The values representing transmittance may be normalized transmission ratios. Alternatively, or in addition, the values representing transmittance may be light signals measured in voltage. Moreover, a closed loop control system may be provided, which is coupled to the one or more heating lamps and the computing device. The wavelength of the infrared light provided by the first signal generator can be 1200 nm.

In a further embodiment, a second signal generator is configured to pulse a second signal, wherein the second signal generator is optically coupled through a window in the substrate support assembly; and a second sensor positioned to receive energy transmitted from the second signal generator through the window to which the second signal generator is coupled, wherein the second sensor is configured to detect a metric indicative of transmittance. The second signal can be infrared light of a shorter wavelength than the first signal. The apparatus may also further comprise a log detector. Alternatively, the second signal can be infrared light of a longer wavelength than the first signal.

Other embodiments provide a method of measuring a substrate temperature during an etching process comprising: providing a substrate in a process chamber at a starting temperature less than a transition point in transmittance for a first infrared wavelength; heating the substrate using radiant energy; pulsing a first light having a wavelength approximately equal to the first infrared wavelength; determining a metric indicative of total transmittance through the substrate when the first light is pulsed on; determining a metric indicative of background transmittance through the substrate when the first light is pulsed off; and determining a process temperature of the substrate based on transmittance of the first infrared wavelength from the first light through the substrate. The first light may be a laser.

The method may further comprise isolating a metric indicative of transmittance through the substrate from the laser without the background transmittance. Or, the method may further comprise: subtracting (a) the metric indicative of background transmittance through the substrate when the first light is pulsed off from (b) the metric indicative of total transmittance through the substrate when the first light is pulsed on. The wavelength of the infrared laser light can be 1200 nm, and the heating step can further comprise powering on one or more heating lamps. The metric of transmittance can be either a normalized transmission ratio or a light signal measured in voltage.

In another embodiment, the method may further comprise cooling the substrate while determining the process temperature. In yet another embodiment, the method may further comprise: using a control system to change the amount of power supplied to the one or more heating lamps based on the process temperature of the substrate. In an additional embodiment, the method may comprise pulsing a second light having a second infrared wavelength, which is different from the first infrared wavelength. A further embodiment may comprise pulsing a third light having a third infrared wavelength, which is different from both the first and second infrared wavelengths.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-C depict simplified schematic diagrams of an exemplary processing apparatus suitable for practicing certain embodiments.

FIG. 2 depicts a graph illustrating silicon substrate transmissivity verses substrate temperature at a certain IR light wavelength.

FIG. 3 depicts a graph illustrating silicon substrate transmissivity verses substrate temperature at certain IR light wavelengths.

FIG. 4 depicts a graph illustrating light intensity and substrate transmissivity verses substrate temperature at a certain IR light wavelength for linear measurements and log measurements.

FIG. 5A depicts a schematic diagram of an exemplary processing apparatus configured to practice the present invention.

FIGS. 5B-C depict top views of different embodiments of a substrate support assembly disposed in the processing apparatus of FIG. 5A.

FIG. 6 depicts a schematic diagram of an exemplary processing system having at least one of the apparatuses of FIG. 5A incorporated thereto to practice the present invention.

FIG. 7 depicts a schematic diagram of an exemplary processing system having at least one of the apparatuses of FIG. 5A incorporated therein.

FIG. 8 depicts a graph illustrating process steps for a prior art method.

FIG. 9 depicts a graph illustrating light intensity or transmission ratio versus wafer temperature.

FIG. 10 depicts a graph illustrating laser and lamp signals during heating.

FIG. 11 provides a table showing temperature resolution by number of samples and heating rate for 20 Hz sampling.

It is contemplated that elements and features of one embodiment may be beneficially incorporated in other embodiments without further recitation. It is to be noted, however, that the drawings illustrate only exemplary embodiments of this invention and are therefore not to be considered limiting of its scope, for the invention may admit to other effective embodiments.

### DETAILED DESCRIPTION

Embodiments discussed herein provide methods and apparatuses for measuring a substrate temperature during heating or cooling processes, such as may be used in etching. Other example processes may include plasma processes such as etching, deposition, annealing, plasma surface treating and ion implantation, among others. In one embodiment, the substrate temperature may be determined by monitoring the transmittance of energy through a substrate. In a further embodiment, an energy source, such as a laser emitting infrared (IR) light, may be turned on and off during a process to allow subtraction of other energy sources from the transmission measurement. Various details regarding substrate temperature measurement by infrared transmission may be found in U.S. Pat. No. 7,946,759 and in U.S. patent application Ser. No. 12/144,157, which are both incorporated by reference as if fully set out herein.

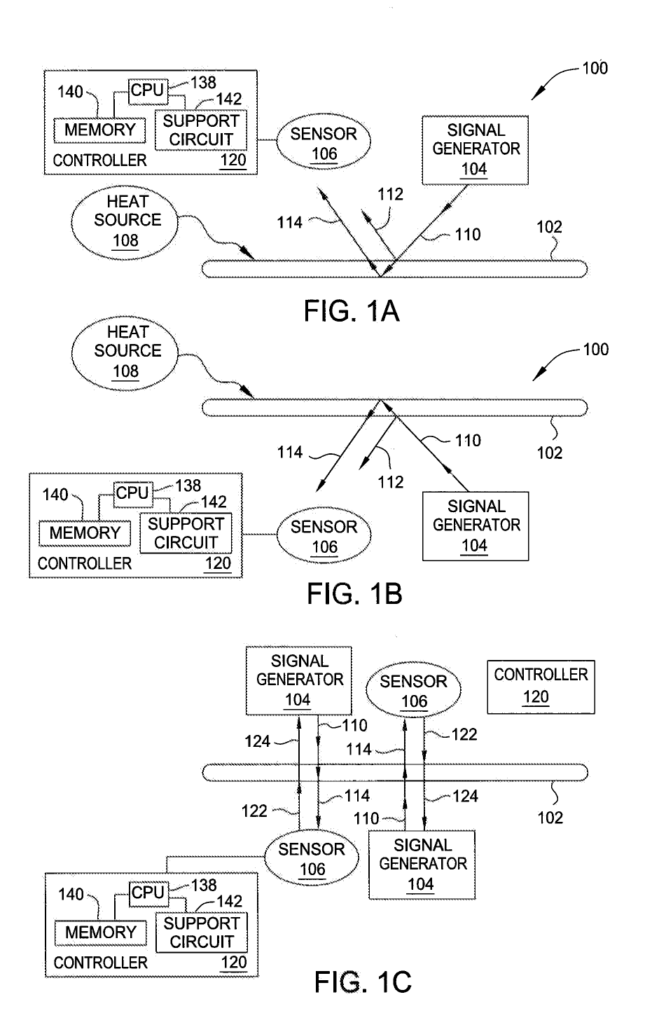

FIGS. 1A-1C depict a simplified schematic diagram of a processing apparatus suitable for practice the present invention. The apparatus 100 is operated under vacuum. The apparatus 100 includes a heat source 108 adapted to provide thermal energy to a substrate 102 disposed in the apparatus 100. In one embodiment, the heat source 108 is provided from a plasma generated adjacent to the substrate 102. In another embodiment, the heat source 108 may alternatively be provided by a heated substrate holder, a heated support pedestal, a resistive heater or other heat source suitable for raising the temperature of the substrate.

In the embodiment depicted in FIG. 1A, a signal generator 104 and a sensor 106 are disposed above an upper side of the substrate 102. The signal generator 104 is disposed above the substrate 102 and generates a signal 110 that is transmitted through the substrate 102. The signal generator 104 may be an energy source that provides energy having at least one wavelength that may be transmitted through the substrate 102, and may include lasers or broad band light sources. As the signal 110 hits the substrate 102, a first portion 112 of the signal 110 is directly reflected from the upper surface of the substrate. A second portion of the signal 110 is transmitted through the substrate 102 and may be partially absorbed by the substrate 102. The second portion of the signal 110 transmitted through the substrate 102 may be reflected from a bottom of the substrate 102 to provide a sensor portion 114 of the signal 110, which may be detected by a sensor 106. The sensor 106 is utilized to receive the sensor portion 114 of the signal 110 reflected off the bottom of the substrate 102. A filter (not shown) may be employed to screen the first portion 112 of the signal 110 reflected to the sensor 106 which has not passed through the substrate 102.

A controller 120 is connected to the sensor 106 to analyze the signal received. The controller 120 generally includes a central processing unit (CPU) 138, a memory 140, and a support circuit 142. The CPU 138 may be one of any form of a general purpose computer processor that can be used in an industrial setting. The support circuit 142 is conventionally coupled to the CPU 138 and may comprise cache, clock circuits, input/output subsystems, power supplies, and the like. The software routines when executed by the CPU 138, transform the CPU 138 into a specific purpose computer (controller) 144. The software routines may also be stored and/or executed by a second controller (not shown) that is located remotely from the apparatus 100.

Similar to the configurations of FIG. 1A, FIG. 1B depicts another embodiment wherein the signal generator 104 and the sensor 106 are disposed below a bottom side of the substrate 102.

FIG. 1C depicts yet another embodiment wherein the signal generator 104 and sensor 106 are disposed on the opposite sides of the substrate 102. The signal generator 104 is disposed above the substrate 102 and generates a signal 110. The sensor 106 is disposed at a position opposite to the signal generator 104 to receive a sensor portion 114 of the signal 110, which passes through the substrate 102 and is not reflected or absorbed. A secondary reflected signal 122 may be reflected from the sensor 106 and may be transmitted through the substrate 102 such that a portion 124 of the secondary reflected signal 122 passes through the substrate 102 to the upper side of the substrate 102. Accordingly, one or more sets of the signal generator 104 and sensor 106 may be utilized to be disposed in different sides of the substrate 102 to generate and receive signal portions incurred in any directions during the process.

Different substrate materials may result in different transmittance of light at different temperatures and different wavelengths. As the heat source 108 provides thermal energy to the substrate surface, the substrate temperature changes. A sensor portion 114 of the signal 110 is transmitted through the substrate 102 while another portion is absorbed. The amount of the signal transmitted through the substrate 102 is dependent on the temperature of the substrate 102. Thus, as the substrate 102 is heated, changes occur in the sensor portion 114 of the signal 110 that is transmitted through the substrate 102 to the sensor 106. The sensor 106 detects the changes in the sensor portion 114 of the signal 110, which are indicative of the temperature of the substrate 102. The substrate temperature may be determined based on the change of detection of the sensor portion 114 of the signal 110.

In one embodiment, the signal generator 104 may be a light generator having different wavelengths. For example, the signal generator 104 may provide a laser beam having a narrow band of wavelength centered in a desired range or at a desired value. The range may be selected between about 1000 nm and about 1500 nm. In further embodiments, a laser may be used having a wavelength of approximately 1080 nm, 1200 nm or 1310 nm.

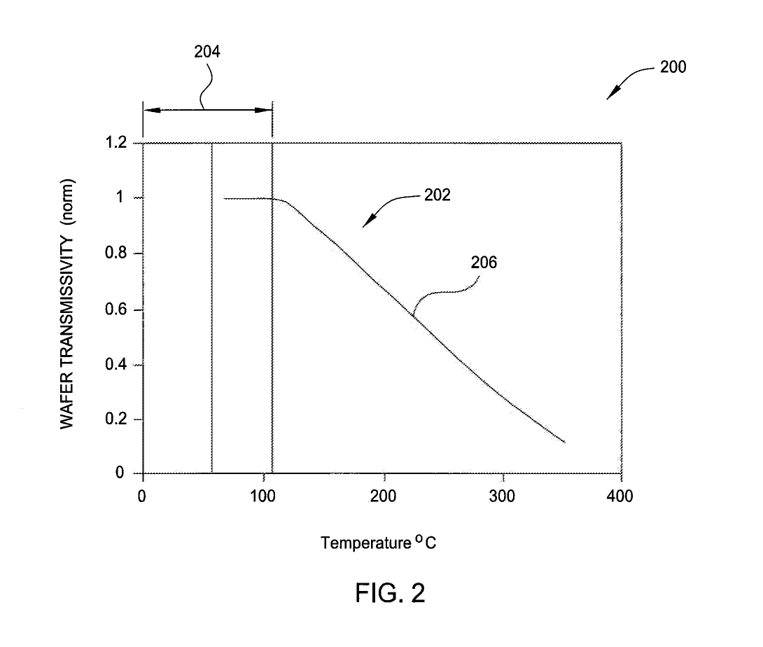

FIG. 2 depicts substrate light transmissivity as the substrate temperature elevates, measured at a wavelength of about 1200 nm. A trace 202 depicts the transmissivity of silicon semiconductor material as a function of temperatures between about 60 degrees Celsius and about 300 degrees Celsius. As the substrate is at a temperature below 60 degrees Celsius, the substrate light transmissivity remains constant, as shown in a first temperature zone 204, and is normalized as a base line relative to what is measured of the subsequent data points. As the substrate temperature elevates over a certain value, such as greater than 120 degrees Celsius, a change in substrate transmissivity occurs. Accordingly, a slope 206 of trace 202 changes. As the substrate temperature increases, the substrate loses its transparency. Accordingly, based on the energy intensity measured, a substrate temperature may be determined.

In various processes, rapid heating of a silicon wafer is needed, and temperature readings may be difficult to access. For example, in some etching processes, a silicon wafer may need to be heated to approximately 300° C. over a time period of about 5-30 seconds. This rapid heating may be used to facilitate the rapid decomposition of incident ozone. Lamps are often used for providing heat, and the power supplied to the lamps can determine the amount of heating provided. The power level may be altered during a process to change the heating rate. Thus, for rapid heating, a ramp step may be used to raise the temperature of the wafer quickly, such as by providing a high power level to the lamps. When a certain temperature is reached, the power level may be lowered or even turned off. During this heating process, light from the lamps that is transmitted through the wafer may be measured to determine the temperature of the silicon wafer, as discussed above. However, this method is only able to determine temperatures during the ramp step, the temperature range is limited, and the method is limited to the opacity of certain wafers. Further, there may be limited light available at the desired wavelength (such as 1200 nm) for use in filtering broadband light to the desired wavelength for detection. When the lamp power changes during a specific recipe, the ability to reference the initial band edge transmission is lost and temperature is indeterminate. (Because the amount of IR radiation transmitted through a silicon wafer shifts as a function of temperature, certain wavelengths are absorbed or transmitted at certain temperatures. The lowest wavelength transmitted changes with temperatures.)

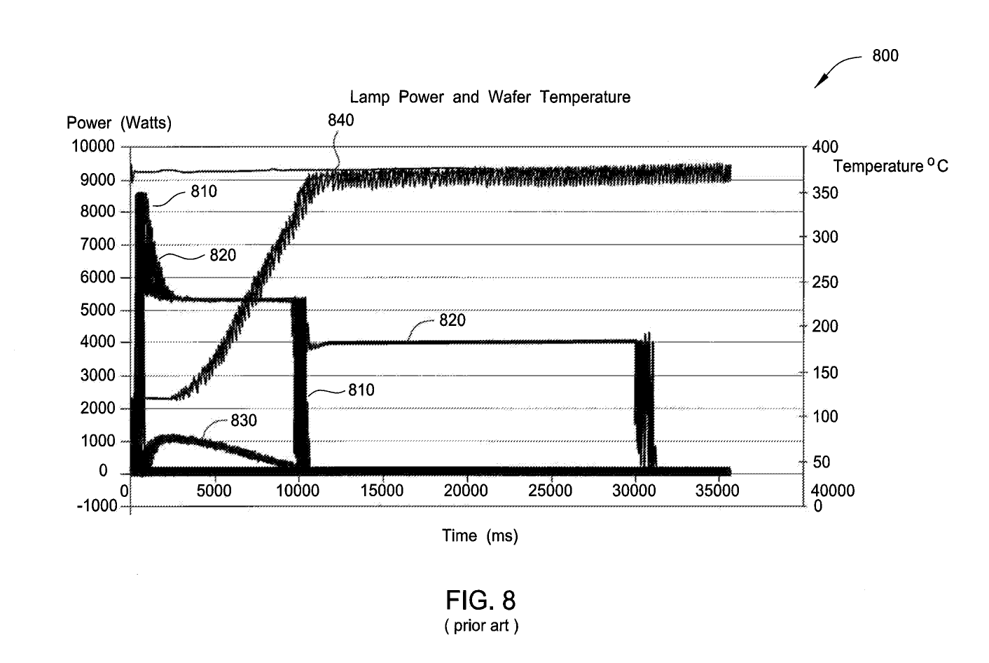

An example prior art process is illustrated in FIG. 8. Trace 810 and trace 820 illustrate first and second power drivers, respectively, for heating lamps. The power is measured in Watts on the left scale. Trace 830 illustrates the shape of an actual signal reading (in volts, not shown). Trace 840 illustrates a calculated temperature (in ° C. on the left scale) based on the signal reading illustrated by trace 830. The traces are shown as a function of time in milliseconds on the bottom scale. As shown, the lamps are initially powered up quickly for a few seconds, and then the power is lowered. At the ten second mark, the first power driver illustrated by trace 810 is shut off, and the second power driver illustrated by trace 820 is lowered until it is also shut off at the thirty second mark. As illustrated, there is uncertainty regarding the temperature calculation during the initial ramping up step over the first few seconds. The temperature profile is then determined at values over 120° C. using the trace 840, but only until the ten second mark, when the signal reading illustrated by trace 830 flattens out at zero, around a temperature estimation near or over about 360° C.

Stated another way, a transmission ratio, which is needed to determine the temperature, can only be determined for the portion of time that the signal reading illustrated by trace 830 is sloping downwards. Further, the temperature cannot be measured during subsequent cooling steps.

The use of an independent source (such as a laser diode) allows the lamp power to change during processing while the laser output is used for temperature calculation. When the signal generator 104 is used, the lamps may emit radiation in the same wavelength range as the signal generator 104. This radiation creates background “noise” that must be accounted for in determining the temperature of the wafer throughout the process. Such background radiation can impose limits on temperature measurements.

An improved method of determining the temperature can be provided by pulsing the laser. The combination of laser and lamp output can be collected by a photodetector and compared to values collected when the laser is off. The values with the laser is off can be subtracted from the values with the laser is on, so that the laser signal can be isolated from the background noise (lamps). The decreasing laser signal can be compared to a wavelength-specific look-up table correlating signal ratio to temperature, enabling the determination of wafer temperature, independent of lamp power. (Temperature correlations can also be applied through math formulas or through computer programming with a database.) This enables the temperature to be known through all steps of the recipe. Otherwise, the power in the hold steps may need to be determined using a thermocouple wafer, and the user has to trust that this temperature is maintained during each wafer run. However, pulsing a laser allows process tuning to be improved, and temperature issues during the recipe are more easily detected. In addition, temperature can be known during cooling and can be used to optimize cooling time and throughput. Further, the higher overall signal allows extension of the measurable temperature range.

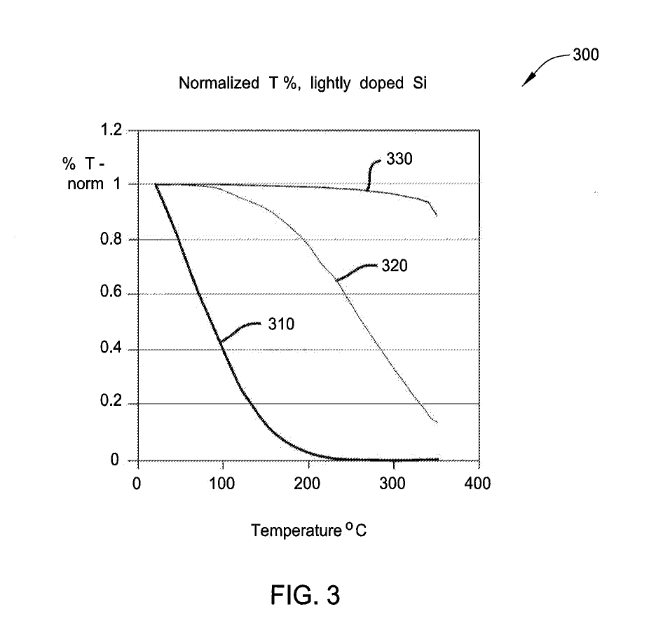

Three wavelengths were investigated for lightly and heavily doped silicon: 1080 nm, 1200 nm, and 1310 nm. Doping ranges were tested over six orders of magnitude to verify the robustness of the various embodiments. FIG. 3 shows the transmission change versus temperature. Transmission change is illustrated by the normalized transmission ratio on the left scale. Temperature is illustrated on the bottom scale. Trace 310 illustrates a wavelength of 1080 nm, trace 320 illustrates a wavelength of 1200 nm, and trace 330 illustrates a wavelength of 1310 nm. It should be appreciated that other wavelengths may also be used.

FIG. 3 illustrates that the 1200 nm wavelength shows the best temperature sensitivity over the range of about 120° C. to 350° C. However, the 1200 nm wavelength also shows the most background noise from the lamps. Thus, the 1200 nm wavelength is more difficult to use, unless a laser pulsing method is employed. The 1080 nm signal has lower background noise, but its band edge is at a lower temperature, making it more difficult to determine the temperature of incoming wafers, which can vary. As illustrated by trace 310, the 1080 nm signal drops to a near zero value near 200° C., and thus may not be suitable on a linear scale for temperatures above that range. FIG. 3 illustrates that a 1310 nm source is relatively insensitive over the 120° C. to 350° C. range, but does show declining transmittance ratio at temperatures over 300° C.

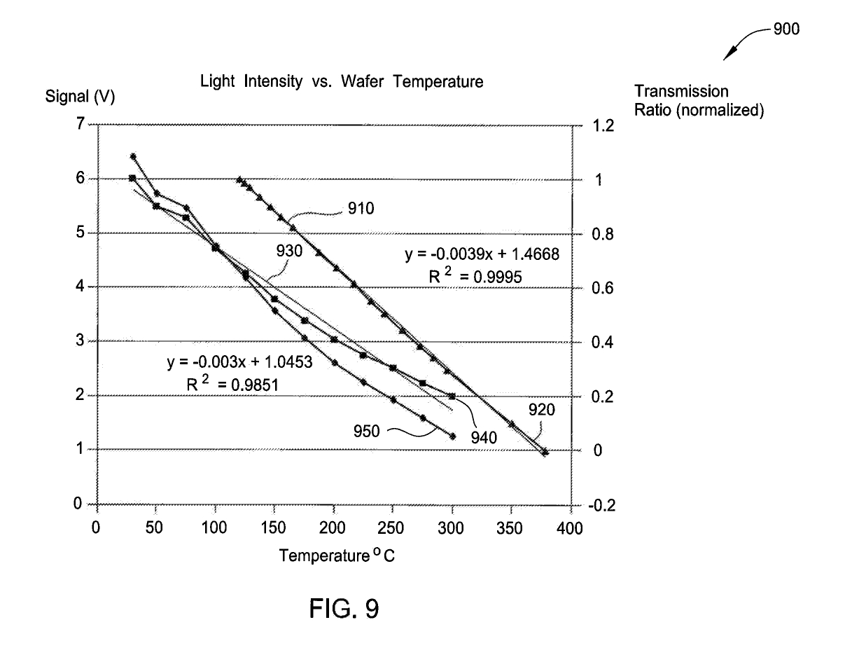

FIG. 9 illustrates light intensity versus wafer temperature in a graph showing signal measurement in volts or normalized transmission ratio as a function of temperature in Celsius. FIG. 9 illustrates that the 1200 nm wavelength shows a linear slope over much of the desired temperature range. The inventors also found that for a 1200 nm laser (˜200 mW), a detector measuring signal strength in volts yielded results very nearly linear when plotted against temperature, thus greatly simplifying temperature determinations for this wavelength. These results are illustrated in FIG. 9 by line 910 passing through a 1200 nm data point trace 920. Results for a 1080 nm laser are illustrated by a first 1080 nm data point trace 940 for transmission ratio and a second 1080 nm data point trace 950 for the signal detected in volts. A line 930 illustrates that the 1080 nm data points are not as linear as the 1200 nm data points. However, temperatures can still be correlated for transmission ratio or signal detections for 1080 nm wavelengths, whether by math formulas or data tables or other methods.

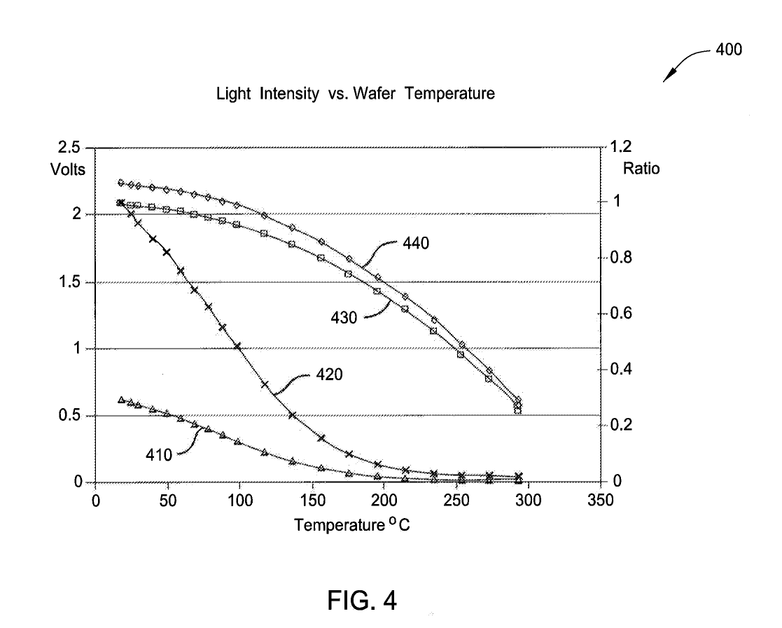

A 1080 nm laser was further examined using a logarithmic photodetector. Results are illustrated in FIG. 4, which depicts light intensity (detected in volts) on the left scale, with temperature in degrees Celsius on the bottom scale. The normalized transmission ratio is depicted at the right scale for certain data sets. The log detector was used due to the steep relation of transmission with temperature at 1080 nm. Data of wafer transmission versus wafer temperature was collected for 1080 nm on a test stand. The response was strongly affected by the adjustment of settings on the detector, which controlled signal level, total range, and bandwidth. Adjustments were made to the detector, but were more complicated than needed for the 1200 nm laser (˜200 mW). In FIG. 4, trace 410 illustrates signal strength (volts) on a linear scale. Trace 420 illustrates the normalized transmission ratio on a linear scale. Trace 430 illustrates the normalized transmission ratio on a log scale, and trace 440 illustrates the signal strength (volts) on a log scale. As shown, the log scale provides a wider range of values for the desired temperature range, which is preferable for determining temperature.

Additionally, the 1080 nm wavelength may be preferred in some instances or for certain reasons. For example, the lamps do not generate as much background signal in the 1080 nm range as in the 1200 nm range. Moreover, as shown in FIG. 3 by trace 310, the 1080 nm wavelength has a transition point at a lower temperature than the 1200 nm wavelength, and thus may be useful in examining temperatures lower than 120° C., which is the approximate transition point of the 1200 nm wavelength. Also, FIG. 3 shows that trace 310 has a relatively linear slope for temperatures less than 150° C., which may make temperature correlations easier in that range.

With a 1200 nm laser, a silicon wafer can be expected to have constant transmission from room temperature up to about 120° C., with lamps at an appropriate power. Above that temperature, the existing transmission correlation can be used. Ratios may be calculated for the peak value at 120° C. to a current value, which correlate to the current temperature. In a process, wafers may come from an etching step at temperatures around 40-60° C. When the wafers are heated to 120° C. at a given lamp power, the transmission is constant. From 120° C. to 377° C., the transmission drops, and the 1200 nm laser can be pulsed to take temperature measurements as discussed above. The 1200 nm wavelength is sufficient to cover wavelengths in this temperature range. Wafers or process steps may also be monitored to make sure that wafers come in below the transition point for the wavelength being used.

Further, a 1080 nm laser could also be used to take temperature measurements below 120° C. Thus, lasers (or light sources) of different wavelengths may be combined. Moreover, a laser (or light source) with a higher wavelength (such as 1310 nm) could be used to extend the range of temperature detection above 377° C. Filtering devices or techniques can also be used to only send a desired wavelength to a detector.

During the heating step, an inert gas, such as argon, can be flowed into the chamber. A fixed flow rate of about 14,500 sccm at 11% concentration can be used at a pressure of 200 Torr. The methods and apparatuses discussed herein may also be used to monitor temperature during cooling, after the heating steps are finished. A wafer may be moved to a cooling station. A substrate support (i.e., a pedestal) may also be water cooled. And the atmosphere may be vented or otherwise controlled to facilitate cooling. Knowing the temperature of the wafer while cooling allows the cooling to be optimized, such that processes may be sped up by knowing when a wafer is cooled to a desired level. In this way, it may be determined instantly that a cooling step is complete. Control loops may also be established for cooling. And active cooling steps can be stopped, such as circulating water in a pedestal or circulating or venting the atmosphere.

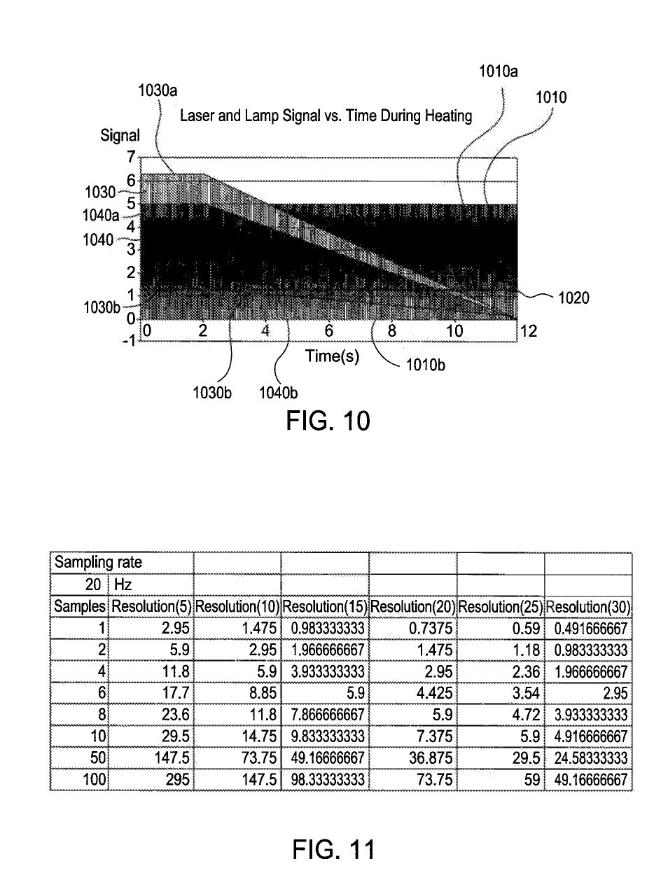

FIG. 10 shows the effects of a pulsed laser turning on and off during a heating process. This is shown as a block of square waves 1010, which are either on or off. In FIG. 10, the area encompassed by the square waves 1010 caused by the pulsed laser is bound on the upper side by line 1010a and bound on the lower side by line 1010b. The lamp light signals 1020 going into the detector are relatively constant in this example. (This is represented by the straight line drawn for lamp light signals 1020 in FIG. 10.) Total optical input during a run is represented by total optical input area 1030, which is the sum of the square waves 1010 of the pulsed laser and the lamp light signal 1020. In FIG. 10, the total optical input area 1030 is bound on the upper side by reference line 1030a and bound on the lower side by reference line 1030b, which are drawn merely to facilitate understanding. The isolated laser optical input 1040 is represented by the area bound on the upper side by reference line 1040a and bound on the lower side by reference line 1040b. The isolated laser optical input 1040 is dropping because the transmission is decreasing during the heating process. The increase in signal (from ˜1V to 5+V) can improve the upper temperature measurement limit to about 370° C. from 320° C. and extends endpoint detection capability to more opaque wafers. This improves process repeatability between wafers and chambers. The temperature resolution can be determined by the ramp rate and the sampling rate.

Calculations show that the available sampling rate will limit resolution and noise filtering. Process testing will determine power level, pulsing rate, and sampling rate requirements. FIG. 11 illustrates how resolution and sampling rate can be determined for various heating rates. In FIG. 11, a laser is operated at 20 Hz. The laser is pulsed in a square wave, such that it is on for 25 milliseconds and off for 25 milliseconds (for a period of 50 ms). The setting of 20 Hz was determined by the limit of the hardware available. However, FIG. 11 also illustrates how one may determine how fast to pulse a laser for a desired temperature resolution. Thus, it should be appreciated that other settings may be used to generate other pulse lengths. The time in seconds is given in the parenthetical following the term “Resolution” in each column. Thus, the first “Resolution (5)” column represents that a heating rate was provided over five seconds to raise the temperature from 20° C. to 320° C. The Samples column represents the number of points to get each measurement. The Resolution represents the temperature resolution provided by the number of samples. One sample at a five second heating rate provides a temperature resolution of 2.95° C., which can represent an error range in the temperature reading. (If one hundred samples were taken to collect a single temperature reading, the resolution would be 295° C., which shows the temperature is changing too fast to determine with 100 samples.) The heating rate may be predetermined by the process being used. Processes may be preferred to run as fast as possible as long as uniformity is good. Thus, FIG. 11 illustrates the resolution that may be obtained with the available hardware and processes. As shown, greater resolution is provided for longer heating rates than shorter heating rates.

The embodiments discussed above may also be used in various combinations. For example, lasers and/or detectors may be used at different wavelengths to extend the measurement range or provide other advantages. In some embodiments, higher wavelengths may be used for higher ranges of temperatures, and/or lower wavelengths may be used for lower ranges of temperatures. Moreover, methods or devices using a log scale or a log scale detector may be combined with linear methods or devices. Additional lasers and/or detectors may also be to measure temperature at multiple locations on a wafer. In this way, uniformity can be verified or checked. Further, the improved temperature measurement methods provided herein can be used to control lamp power and/or timing more precisely. A control loop may be set up to provide lamp power control, and the control loop may be a closed loop system. Further, multiple lamps may be used, wherein different control protocols are applied to different lamps or different sets of lamps. Thus, some lamps may be controlled at higher power than others, and/or some lamps may be turned off or have their power lowered sooner than others. Computer programs and/or hardware may also be used to subtract out background noise from measurements, and to make temperature determinations.

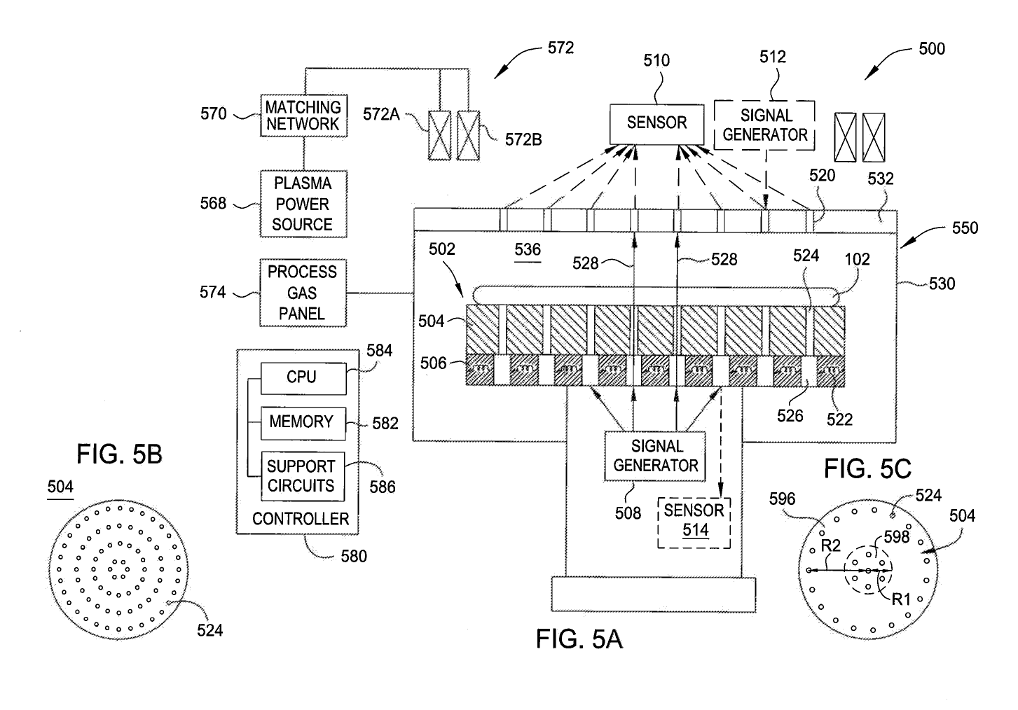

FIG. 5A depicts one embodiment of a process chamber 500 that can be utilized to perform an etch or other plasma process on a substrate, such as the substrate 102 of FIG. 1A-C. The process chamber 500 includes one embodiment of a substrate support assembly 502 (which may be a pedestal assembly for supporting a substrate) and a chamber lid 532 that may illustratively be used to practice the invention. The particular embodiment of the process chamber 500 shown herein is provided for illustrative purposes and should not be used to limit the scope of the invention. In one embodiment, the process chamber may be a HART™ chamber available from Applied Materials, Inc. Alternatively, other process chambers, including those from other manufacturers, may be adapted to benefit from the invention.

The process chamber 500 generally includes a process chamber body 550, a gas panel 574 and a controller 580. The process chamber body 550 includes a conductive body (wall) 530 and the chamber lid 532 that enclose a process volume 536. Process gasses are provided to the process volume 536 of the process chamber 500 from the gas panel 574.

The controller 580 includes a central processing unit (CPU) 584, a memory 582, and support circuits 586. The controller 580 is coupled to and controls components of the process chamber 500, processes performed in the process chamber 500, as well as may facilitate an optional data exchange with databases of an integrated circuit fab.

In one embodiment, at least one signal generator 508 is positioned relative to the process chamber signal for substrate temperature measurement will impinge at least a portion of a substrate supported on the substrate support assembly 502. At least one sensor 510 is positioned to receive a portion of the signal generated from the signal generator 508 transmitted through the substrate. In certain embodiment, one or more pairs of the second signal source 512 and the second sensor 514 may be utilized to detect substrate temperature at different regions of the substrate. Configuration and arrangement of the signal generators and sensors may be similar to the configurations of the signal generator 104 and the sensor 106 discussed above with referenced to FIGS. 1A-C.

In one embodiment, the signal generator 508 is laser or other light source that may provide infrared radiation having a wavelength between about 1000 nm and about 1400 nm, such as between about 1050 nm and about 1300 nm, for example, between about 1100 nm and about 1200 nm. The wavelength of the signal generator 508 is selected to have a high change in transmittance through the materials and/or films being processed in the range of temperature for which measurement is sought, for example, a temperature of a substrate during an etch process.

In one embodiment, the sensor 510 is an InGaAs diode sensor. The sensor 510 detects collected energy passing through substrate 102. A filter (not shown) may be disposed adjacent to the sensor 510 to filter the signal collected and only allow IR light within a desired wavelength to reach the sensor 510. The sensor 510 provides a metric indicative of the light energy reaching to the sensor 510 which is then further analyzed by the controller 580 to calculate the temperature of the substrate 102.

In the depicted embodiment, the chamber lid 532 is a substantially flat dielectric member. Other embodiments of the process chamber 500 may have other types of ceilings, e.g., a dome-shaped ceiling. Above the chamber lid 532 is disposed an antenna 572 comprising one or more inductive coil elements (two co-axial coil elements 572A and 572B are illustratively shown). The antenna 572 is coupled, through a first matching network 570, to a radio-frequency (RF) plasma power source 568.

In one embodiment, the chamber lid 532 may have a plurality of window plugs 520 formed therein. The window plugs 520 may be removable to facilitate ease of replacement of the window plugs 520. In one embodiment, the window plugs 520 are optical access windows that allow light from the signal generator 508 to pass through the windows to the sensor 510. It is noted that configurations, arrangement and functions of the signal generator 508 and the sensor 510 are similar to the signal generator 104 and the sensor 106 described above with referenced to FIGS. 1A-C.

In one embodiment, the substrate support assembly 502 includes an electrostatic chuck 504 disposed on a base plate 506. Associated description of other substrate support assembly components and parts necessitated to compose the substrate support assembly 502 is hereby eliminated for the sake of brevity. One embodiment of the substrate support assembly 502 used herein may be referenced to United States Patents Application No. 2006/0076108 published to Holland, which is hereby incorporated by reference.

In one embodiment, the substrate support assembly 502 further comprises at least one optional embedded heater 522 or a plurality of optional conduits (not shown) facilitated to supply heating or cooling liquid to the substrate support assembly 502. The heater 522 and the conduits are utilized to control the temperature of the substrate support assembly 502, thereby controlling the temperature of a substrate 102 disposed thereon during etching processing.

In one embodiment, a plurality of window plugs 524 are formed within the body of the electrostatic chuck 504 to facilitate transmission of signals from the signal generator 508. The base plate 506 may also have a plurality of apertures and/or window plugs 526 formed therein that align with the window plugs 524 formed in the electrostatic chuck 504. The aligned sets of window plugs 526 and window plugs 524 in the base plate 506 and the electrostatic chuck 504, respectively, allow the signal 528 from the signal generator 508 to pass therethrough with minimal refraction. In the embodiment wherein the sensor and the signal source are at opposite side of the substrate 102 as depicted in FIGS. 5A and 1C, the aligned sets of window plugs 526 and window plugs 524 formed in the substrate support assembly 502 are further aligned with the window plugs 520 formed in the chamber lid 532 to facilitate light transmission therethrough to the sensor 510 disposed above the chamber lid 532. Furthermore, the aligned sets of window plugs 526 and window plugs 524 also facilitates signals from a second signal source 512 disposed above the chamber lid 532 to pass therethrough to a second sensor 514 disposed below the substrate support assembly 502.

In one embodiment, number and distribution of the window plugs 524, 526, 520 formed in the substrate support assembly 502 and the chamber lid 532 are configured in a manner to enable detection of temperature uniformity across the entire substrate surface, for example, in at least edge and center locations. Different configurations and distribution of the window plugs 524, 526, 520 facilitate signals to be transmitted to different regions and zones of the substrate for detection of each pinpoint temperature located at different regions and zones across the substrate surface. Once each pinpoint substrate temperature is determined, a temperature uniformity and temperature profile of the substrate 102 may be obtained. Accordingly, the heating or cooling fluid supplied to control the temperature of the substrate support assembly 502 may be adjusted in accordance with the measured temperature profile to control and maintain the overall substrate temperature uniformity.

In one embodiment, the window plugs 524, 526, 520 may be fabricated from quartz, sapphire and other ceramic material transmissive to the sensing signal and compatible with the materials selected to fabricate the substrate support assembly 502 and the chamber lid 532. The window plugs 524, 526, 520 may be in form of plugs that can easily be removed and replaced from the substrate support assembly 502 and the chamber lid 532. The window plugs 524, 526, 520 may be sintered, clamped or mounted by other suitable manner to the substrate support assembly 502 and the chamber lid 532.

It is noted that the window plugs 524, 526 may be formed only in the substrate support assembly 502, similar to the configuration described in FIG. 1B, or the window plugs 520 may be formed only in the chamber lid 532, similar to the configuration described in FIG. 1A. Alternatively, the window plugs 524, 526, 520 may be formed in both the chamber lid 532 and the substrate support assembly 502, similar to the configuration described in FIG. 1C and FIG. 5A.

FIG. 5B depicts a top view of the electrostatic chuck 504 having the window plugs 524 sintered and mounted therein. The window plugs 524 may be uniformly distributed across the surface of the electrostatic chuck 504 that allows signal to be passed therethrough to detect substrate temperature. Each window plug 524 formed therein may be substantially equal distance to each other and adapted to measure different regions and zones of the substrate temperature. Similarly, the distribution and configuration of the window plugs 520 formed in the chamber lid 532 may be similarly configured to allow signal to be passed therethrough to detect temperature in different regions of the substrate by a change in transmissivity.

FIG. 5C depicts a top view of another embodiment of the electrostatic chuck 504 having different numbers and configurations of the window plugs 524 sintered and mounted therein. The electrostatic chuck 504 may have a center zone 598 having a first radius R1 and a periphery zone 596 having a second radius R2. The first radius R1 may have a length between about 0 mm and about 75 mm and the second radius R2 may have a length between about 75 mm and about 150 mm. Alternatively, the second radius R2 may be controlled at a length about double or triple the length of the first radius R1. The window plugs 524 may be substantially formed within the center zone 598 and/or formed in the periphery zone 596 configured in the electrostatic chuck 504. Alternatively, the window plugs 524 may be formed in any configuration or distribution as needed.

In operation, the substrate 102 is transferred into the process chamber 500 to perform an etch process. It is contemplated that the process chamber 500 may be configured to perform other processes, such as a deposition process, an anneal process, or other any other process that would benefit from substrate temperature measurement. In one embodiment, the substrate 102 may be any substrate or material on which an etch process or other process is to be performed. In one embodiment, the substrate may be a silicon semiconductor substrate having a layer or layers formed thereon utilized to form a structure, such as a gate structure. The substrate may alternatively utilize a mask layer as an etch mask and/or etch stop layer disposed on the substrate to promote the transfer of the features or structures to the substrate. In another embodiment, the substrate a silicon semiconductor substrate having multiple layers, e.g., a film stack, utilized to form different patterns and/or features, such as a dual damascene structure and the like. The substrate may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire, metal layers disposed on silicon and the like. The substrate may have various dimensions, such as 200 mm or 300 mm diameter wafers, as well as rectangular or square panels. In one embodiment, the substrate is a silicon semiconductor substrate.

In one embodiment, the substrate transferred to the process chamber 500 is etched by supplying a gas mixture having at least a halogen-containing gas. Suitable examples of halogen-containing gas include, but not limited to, hydrogen bromide (HBr), chlorine (Cl₂), carbon tetrafluoride (CF₄), and the like. During etching, the light source, such as the signal generator 508 is turned on to provide IR radiation to the substrate surface. In one embodiment, one or more signal generators 508 generate infrared light at wavelengths between about 1000 nm and about 1400 nm, with very high intensity at the measurement wavelength of 1200 nm. In one embodiment, the intensity is between about 50 milliWatts and about 1000 milliWatts. Information from the sensor 510 is utilized on to detect the IR light from the signal generator 508 transmitted through the substrate 102 after the signal generator 508 has reached a steady state output establishing a baseline transmittance reading. The sensor 510 is turned on after the output from the signal generator 508 has been stabilized. In one embodiment, the output is stabilized after between about 2 second and about 5 seconds.

As previously discussed, the transmissivity of the substrate at different substrate temperatures significantly influences the amount of light energy passed through the substrate 102 and further to the sensor 510. As the substrate temperature elevates, the amount of light energy passed through the substrate 102 varies, thereby causing a change of the amount of the light energy transmitted to the sensor 510. Accordingly, the sensor 510 provides a metric indicative of the change in transmissivity which may be utilized to determine the substrate temperature. Based on the metric indicative of the change in transmissivity, the substrate temperature may be accordingly determined. Details regarding how the metric indicative of the change in transmissivity may be obtained in the U.S. patent application Ser. No. 11/676,092 filed by Davis, which is incorporated by reference.

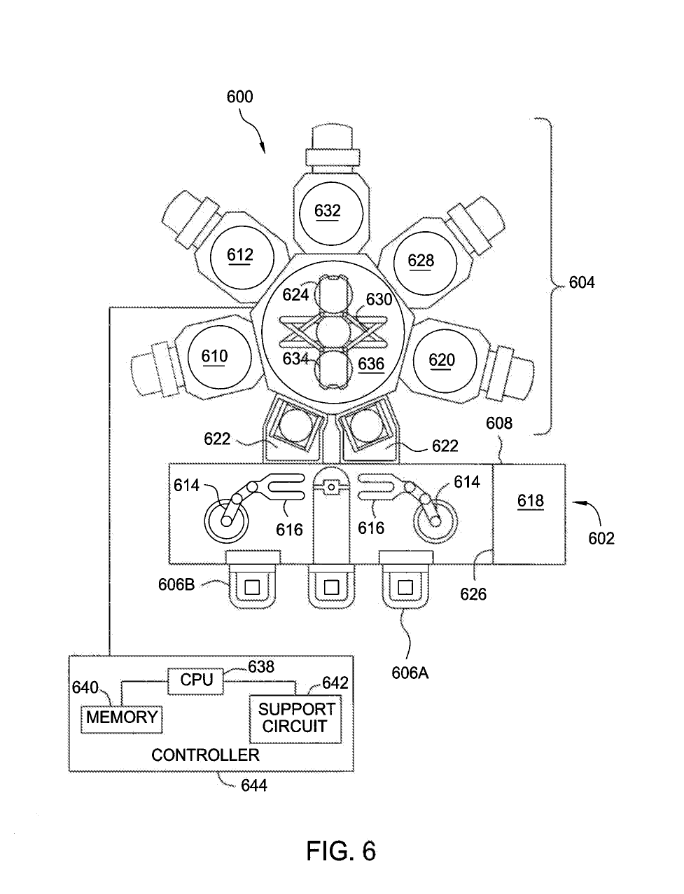

FIG. 6 is a schematic, top plan view of an exemplary processing system 600 that includes at least one region configured to include the process chamber 500 as depicted in FIG. 5 respectively for performing a substrate temperature measure during an etch process. In one embodiment, the processing system 600 may be a suitably adapted CENTURA® integrated processing system, commercially available from Applied Materials, Inc., located in Santa Clara, Calif. Another processing system that may be suitable for etching processes is the AP Solstice process, also available from Applied Materials, Inc. It is contemplated that other processing systems (including those from other manufacturers) may be adapted to benefit from the invention.

The processing system 600 includes a processing platform 604 (which may be vacuum-tight), a factory interface 602, and a system controller 644. The processing platform 604 includes a plurality of process chambers 500, 612, 632, 628, 620 and at least one load lock chamber 622 that are coupled to a vacuum substrate transfer chamber 636. Two load lock chambers 622 are shown in FIG. 6. The factory interface 602 is coupled to the transfer chamber 636 by the load lock chambers 622.

In one embodiment, the factory interface 602 comprises at least one docking station 608 and at least one factory interface robot 614 to facilitate transfer of substrates. The docking station 608 is configured to accept one or more front opening unified pod (FOUP). Two FOUPS 606A-B are shown in the embodiment of FIG. 6. The factory interface robot 614 having a blade 616 disposed on one end of the factory interface robot 614 is configured to transfer the substrate from the factory interface 602 to the load lock chambers 622 of the processing platform 604. Optionally, one or more metrology stations 618 may be connected to a terminal 626 of the factory interface 602 to facilitate measurement of substrates while within the factory interface 602.

Each of the load lock chambers 622 have a first port coupled to the factory interface 602 and a second port coupled to the transfer chamber 736. The load lock chambers 622 are coupled to a pressure control system (not shown) which pumps down and vents the load lock chambers 622 to facilitate passing the substrate between the vacuum environment of the transfer chamber 636 and the substantially ambient (e.g., atmospheric) environment of the factory interface 602.

The transfer chamber 636 has a vacuum robot 630 disposed therein. The vacuum robot 630 has a blade 634 capable of transferring substrates 624 between the load lock chambers 622 and the process chambers 500, 612, 632, 628, 620.

In one embodiment, at least one of the process chambers 500, 612, 632, 628, 620 is an etch chamber. For example, the etch chamber may be a HART™ chamber available from Applied Materials, Inc. For etching, the process chamber 500 may use a halogen-containing gas to etch the substrate 102 disposed therein. Examples of halogen-containing gas include hydrogen bromide (HBr), chlorine (Cl₂), carbon tetrafluoride (CF₄), and the like. During the etching process in any of the process chambers 500, 612, 632, 628, 620, a sensor, such as the sensor 510, 514 of FIG. 5, is used to monitor the signal intensity passed through the substrate during the etching process which is correlated to substrate temperature.

The system controller 644 is coupled to the processing system 600. The system controller 644 controls the operation of the processing system 600 using a direct control of the process chambers 500, 612, 632, 628, 620 of the processing system 600 or alternatively, by controlling the computers (or controllers) associated with the process chambers 500, 612, 632, 628, 620 and the processing system 600. In operation, the system controller 644 enables data collection and feedback from the respective chambers and system controller 644 to optimize performance of the processing system 600.

The system controller 644 generally includes a central processing unit (CPU) 638, a memory 640, and support circuit 642. The CPU 638 may be one of any form of a general purpose computer processor that can be used in an industrial setting. The support circuit 642 are conventionally coupled to the CPU 638 and may comprise cache, clock circuits, input/output subsystems, power supplies, and the like. The software routines when executed by the CPU 638, transform the CPU 638 into a specific purpose computer (controller) 644. The software routines may also be stored and/or executed by a second controller (not shown) that is located remotely from the processing system 600.

A process for detecting a substrate temperature utilizing the apparatus of FIG. 5A-C may comprise providing a substrate into a processing apparatus, such as the process chamber 500 of FIG. 5A. An etching process is performed on the substrate to form features on the substrate. Pulsed light from the light generator (e.g., second signal source 512) is transmitted to the substrate to detect changes in transmittance of the substrate while etching. The detected transmittance is then analyzed. As the transmissibility of the substrate at different substrate temperatures significantly influences the amount of light energy passed through the substrate, based on the change in light transmittance through the substrate, a substrate temperature may be determined based on the metric indicative of the change in transmissivity.

Thus, the present invention provides a method and apparatus for measuring a substrate temperature during an etch process. The method and apparatus advantageously monitors the actual substrate temperature by a sensor during the etch process by measuring the IR transmittance transmitted through the substrate. The opacity of the substrate at different temperature provides different amount of IR transmittance passing through the substrate, thereby assisting the sensor to determine the actual substrate temperature.

Advantageously, embodiments of the invention provide multiple windows that facilitate determining temperature profiles and gradient of a substrate during processing using a non-contact, non-evasive, real-time method.

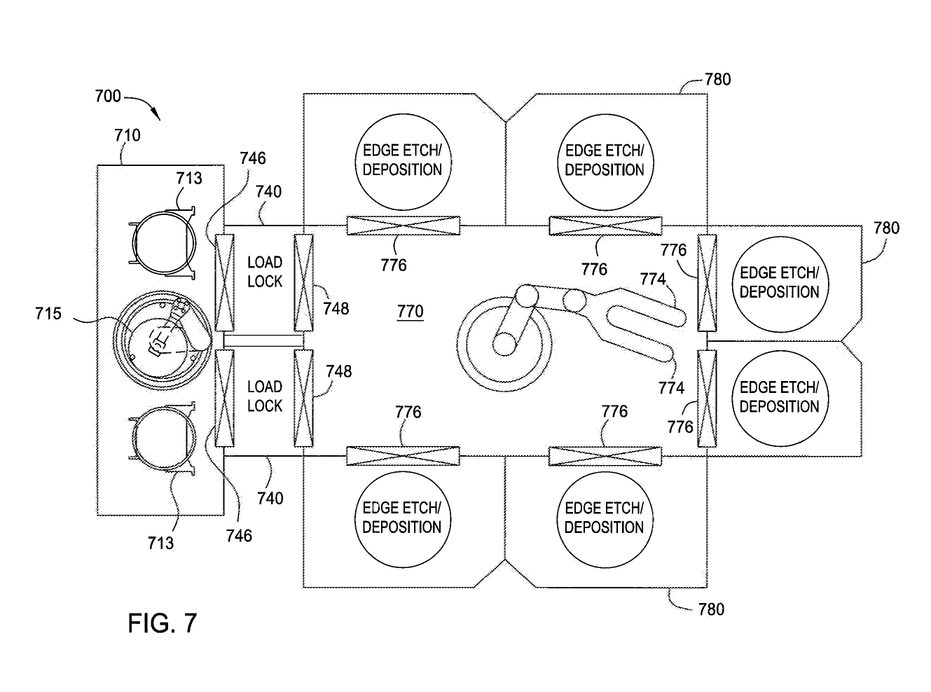

FIG. 7 is a schematic view showing an embodiment of a substrate processing system 700, which may be used in combination with the temperature determination methods and apparatuses set forth herein. (Additional details may be found in U.S. patent application Ser. No. 12/106,881, which is incorporated by reference as if fully set forth herein.) Another processing system that may be suitable for etching processes is the Centris Solstice process, available from Applied Materials, Inc. The substrate processing system 700 comprises a factory interface 710 where substrates are loaded into and unloaded from load lock chambers 740, a substrate transfer chamber 770 housing a substrate-handling robot 772, and a plurality of twin process chambers 780 connected to the transfer chamber 770. The substrate processing system 700 is adapted to accommodate various processes and supporting chamber hardware such as CVD and etch processes. The embodiment described below will be directed to a system that is able to implement a PEVCD to deposit an advanced patterning film including amorphous carbon, and also etch an edge portion of the film deposited on the substrate. However, it is to be understood that other processes are contemplated by the embodiments described herein.

As shown in FIG. 7, the factory interface 710 may include substrate cassettes 713 and a substrate-handling robot 715. Each of the substrate cassettes 713 contains substrates ready for processing. The substrate-handling robot 715 may comprise a substrate mapping system to index the substrates in each substrate cassette 713 in preparation for loading the substrates into the load lock chambers 740.

The transfer chamber 770 includes a substrate-handling robot 772 operable to transfer substrates between the load lock chambers 740 and the twin process chambers 780. More specifically, the substrate-handling robot 272 may have dual substrate-handling blades 774 suitable to transfer two substrates at the same time from one chamber to another. Substrates may be transferred between the transfer chamber 770 and the twin process chambers 780 via slit valves 776. The movement of the substrate-handling robot 772 may be controlled by a motor drive system (not shown), which may include a servo or stepper motor.

While the foregoing is directed to embodiments of the present invention, other and further embodiments of the invention may be devised without departing from the basic scope thereof, and the scope thereof is determined by the claims that follow.

1. An apparatus for measuring a substrate temperature during an etching process, comprising:
a chamber body having a chamber lid enclosing the chamber body;
a substrate support assembly disposed in the chamber body and having a substrate supporting surface;
one or more windows formed in the substrate supporting surface;
a first signal generator configured to pulse a first signal, wherein the first signal generator is optically coupled through the substrate support assembly to the one or more windows such that the pulsed signal may be transmitted through the one or more windows; and
a first sensor positioned to receive energy transmitted from the first signal generator through the one or more windows, wherein the first sensor is configured to detect a metric indicative of transmittance.

2. The apparatus of claim 1, wherein the first signal generator is a laser configured to pulse a wavelength of light, and wherein the first sensor is configured to detect that wavelength of light.

3. The apparatus of claim 2, further comprising: one or more heating lamps, which when powered on can emit light of at least the same wavelength as the first signal generator,
wherein the light is infrared light of a wavelength between about 1000 nm and 1500 nm, and
wherein the first sensor is positioned to detect the wavelength of infrared light from (a) the first signal generator and the one or more heating lamps when the first signal generator is pulsed on, and (b) the one or more heating lamps when the first signal generator is pulsed off.

4. The apparatus of claim 3, further comprising a computing device programmed, wired or otherwise configured to determine a change in transmission from the first signal passing through a substrate positioned on the substrate supporting surface,
wherein the computing device subtracts (a) values representing transmittance of infrared light through the substrate from the one or more heating lamps when the first signal is pulsed off, from (b) values representing transmittance of infrared light through the substrate from the one or more heating lamps and the first signal when the first signal is pulsed on, and
wherein the computing device determines a temperature of the substrate.

5. The apparatus of claim 4, wherein the values representing transmittance are normalized transmission ratios.

6. The apparatus of claim 4, wherein the values representing transmittance are light signals measured in voltage.

7. The apparatus of claim 4, further comprising a closed loop control system coupled to the one or more heating lamps and the computing device.

8. The apparatus of claim 3, wherein the wavelength of the infrared light provided by the first signal generator is 1200 nm.

9. The apparatus of claim 8, further comprising:
a second signal generator configured to pulse a second signal, wherein the second signal generator is optically coupled through a window in the substrate support assembly; and
a second sensor positioned to receive energy transmitted from the second signal generator through the window to which the second signal generator is coupled, wherein the second sensor is configured to detect a metric indicative of transmittance.

10. The apparatus of claim 9, wherein the second signal is infrared light of a shorter wavelength than the first signal.

11. The apparatus of claim 10, further comprising a log detector.

12. The apparatus of claim 9, wherein the second signal is infrared light of a longer wavelength than the first signal.

13. A method of measuring a substrate temperature during an etching process comprising:
providing a substrate in a process chamber at a starting temperature less than a transition point in transmittance for a first infrared wavelength;
heating the substrate using radiant energy;
pulsing a first light having a wavelength approximately equal to the first infrared wavelength;
determining a metric indicative of total transmittance through the substrate when the first light is pulsed on;
determining a metric indicative of background transmittance through the substrate when the first light is pulsed off; and
determining a process temperature of the substrate based on transmittance of the first infrared wavelength from the first light through the substrate.

14. The method of claim 13, wherein the first light is a laser.

15. The method of claim 14, further comprising isolating a metric indicative of transmittance through the substrate from the laser without the background transmittance.

16. The method of claim 14, further comprising: subtracting (a) the metric indicative of background transmittance through the substrate when the first light is pulsed off from (b) the metric indicative of total transmittance through the substrate when the first light is pulsed on.

17. The method of claim 14, wherein the wavelength of the infrared laser light is about 1200 nm, and wherein the heating step further comprises powering on one or more heating lamps.

18. The method of claim 17, wherein the metric of transmittance is either a normalized transmission ratio or a light signal measured in voltage.

19. The method of claim 18, further comprising cooling the substrate while determining the process temperature.

20. The method of claim 13, further comprising pulsing a second light having a second infrared wavelength, which is different from the first infrared wavelength.
